(19) United States
(12) Patent Application Publication
(10) Pub. No.: US 2012/0068306 A1
(43) Pub. Date: Mar. 22, 2012

(54) SEMICONDUCTOR PACKAGE INCLUDING DECOUPLING SEMICONDUCTOR CAPACITOR

(76) Inventors: Sang-Sub SONG, Suwon-si (KR); Sung-Hoon Chun, Hwaseong-si (KR); Sang-Ho An, Suwon-si (KR); Joon-Young Oh, Seongnam-si (KR); Dong-Ok Kwak, Suwon-si (KR)

(21) Appl. No.: 13/230,875

(22) Filed: Sep. 13, 2011

(30) Foreign Application Priority Data
Sep. 20, 2010 (KR) 10-2010-0092656

(51) Int. Cl. H01L 27/08

(52) U.S. Cl. 257/532; 257/E27.048

(57) ABSTRACT

A semiconductor package includes a packaging substrate including a first bond finger and a second bond finger, a first semiconductor chip mounted on the packaging substrate, and including a first chip pad and a second chip pad, the first bond finger being electrically connected to the first chip pad by a first bonding wire, and the second bond finger being electrically connected to the second chip pad by a second bonding wire, and a first decoupling semiconductor capacitor mounted on the first semiconductor chip, and including a first capacitor pad, the first capacitor pad being electrically connected to the second chip pad.

### CROSS REFERENCE TO RELATED APPLICATION

This application claims priority under 35 U.S.C. §119 to Korean Patent Application No. 10-2010-0092656 filed on Sep. 20, 2010, the disclosure of which is hereby incorporated by reference in its entirety.

### BACKGROUND

1. Field

Embodiments relate to a semiconductor package including a decoupling semiconductor capacitor.

2. Description of Related Art

With increasingly high integration and high speed of semiconductor devices, issues of signal/power integrity related to distributions inside and outside semiconductor chips and packaging may occur, affecting performance of a total system. For example, switching noise occurring at a ground surface and a power supply terminal, e.g., from high speed simultaneous switching of the semiconductor chips, and voltage drops may affect performance.

### SUMMARY

An embodiment is directed to a semiconductor package, including a packaging substrate including a first bond finger and a second bond finger, a first semiconductor chip mounted on the packaging substrate, and including a first chip pad and a second chip pad, the first bond finger being electrically connected to the first chip pad by a first bonding wire, and the second bond finger being electrically connected to the second chip pad by a second bonding wire, and a first decoupling semiconductor capacitor mounted on the first semiconductor chip, and including a first capacitor pad, the first capacitor pad being electrically connected to the second chip pad.

The first capacitor pad may be electrically connected to the second chip pad by a third bonding wire.

The first semiconductor chip may further include a land that is electrically connected to the second chip pad by a distribution line formed on an upper surface of the first semiconductor chip or within the first semiconductor chip, and the land may be electrically connected to the first capacitor pad by a flip chip bonding method.

The first decoupling semiconductor capacitor may include the first capacitor pad, a capacitor substrate, a lower electrode on the capacitor substrate, a dielectric layer on the lower electrode, an upper electrode on the dielectric layer, the first capacitor pad being electrically connected to the upper electrode, and a second capacitor pad electrically connected to the lower electrode.

The second bond finger may include a bond finger for ground, the second chip pad may include a chip pad for ground, the first capacitor pad may include a capacitor pad for ground, and the bond finger for ground, the chip pad for ground, and the capacitor pad for ground may be electrically connected.

The packaging substrate may include a bond finger for power, the first semiconductor chip may include a chip pad for power, the second capacitor pad may include a capacitor pad for power, and the bond finger for power, the chip pad for power, and the capacitor pad for power may be electrically connected.

The first decoupling semiconductor capacitor may include a dummy capacitor pad insulated from the upper electrode and the lower electrode.

The semiconductor package may further include a second semiconductor chip mounted on the packaging substrate, the second semiconductor chip including a third chip pad. The packaging substrate may further include a third bond finger electrically connected to the third chip pad.

The semiconductor package may further include a second decoupling semiconductor capacitor mounted on the second semiconductor chip.

The second decoupling semiconductor capacitor may include a capacitor substrate, a lower electrode on the capacitor substrate, a dielectric layer on the lower electrode, an upper electrode on the dielectric layer, a third capacitor pad electrically connected to the upper electrode, and a fourth capacitor pad electrically connected to the lower electrode.

The packaging substrate may further include a fourth bond finger, the second semiconductor chip may further include a fourth chip pad, and the fourth bond finger, the fourth chip pad, and the third capacitor pad may be electrically connected.

The second semiconductor chip may be mounted between the packaging substrate and the first semiconductor chip.

Another embodiment is directed to a semiconductor package, including a packaging substrate including a first bond finger, a second bond finger, and a third bond finger, a first decoupling semiconductor capacitor mounted on the packaging substrate, the first decoupling semiconductor capacitor including a first capacitor pad, a second capacitor pad, and a third capacitor pad, the first capacitor pad being electrically connected to a first electrode of the first decoupling semiconductor capacitor, the second capacitor pad being electrically connected to a second electrode of the first decoupling semiconductor capacitor, and the third capacitor pad being electrically insulated from the first electrode and the second electrode of the first decoupling semiconductor capacitor, a first semiconductor chip mounted on the packaging substrate, the first semiconductor chip including a first chip pad, a second chip pad, and a third chip pad, a first bonding wire electrically connecting the first bond finger and the first capacitor pad, a second bonding wire electrically connecting the first capacitor pad and the first chip pad, a third bonding wire electrically connecting the second bond finger and the second capacitor pad, a fourth bonding wire directly and electrically connecting the second capacitor pad and the second chip pad, a fifth bonding wire electrically connecting the third bond finger and the third capacitor pad, and a sixth bonding wire electrically connecting the third capacitor pad and the third chip pad.

The first chip pad may be a signal input/output pad, the second chip pad may be a power pad, and the third chip pad may be a ground pad.

The semiconductor package may further include a second semiconductor chip mounted between the packaging substrate and the first semiconductor chip. The first decoupling semiconductor capacitor may be mounted on the second semiconductor chip.

Another embodiment is directed to a semiconductor device package, including a packaging substrate, a semiconductor chip on the packaging substrate, an encapsulant, the encapsulant enclosing the semiconductor chip, the semiconductor chip being between the packaging substrate and the encapsulant, and a semiconductor capacitor device, the semiconductor capacitor device being separate from the semiconductor chip and electrically coupled a power connection of the semiconductor chip, the capacitor device being within the encapsulant.

The power connection may be supplied with a power supply voltage or a ground voltage.

The semiconductor capacitor device may be directly affixed to the semiconductor chip by at least one of an adhesive layer and a solder joint.

The semiconductor capacitor device may be directly affixed to the packaging substrate by at least one of an adhesive layer and a solder joint.

The semiconductor chip may be directly affixed to the packaging substrate by at least one of an adhesive layer and a solder joint.

### BRIEF DESCRIPTION OF THE DRAWINGS

The above and other features and advantages will become more apparent to those of skill in the art by describing in detail example embodiments with reference to the attached drawings, in which:

FIG. 1A illustrates a top view of a three-dimensional (3D) decoupling semiconductor capacitor in accordance with example embodiments;

FIGS. 1B and 1C illustrate cross-sectional views of the 3D decoupling semiconductor capacitor of FIG. 1A;

FIG. 2A illustrates a top view of a semiconductor package in accordance with example embodiments;

FIG. 2B illustrates an internal side view of the semiconductor package of FIG. 2A;

FIG. 3A illustrates a top view of a semiconductor package in accordance with example embodiments;

FIG. 3B illustrates an internal side view of the semiconductor package of FIG. 3A;

FIGS. 4A to 4H illustrate top views and internal side views of semiconductor packages in accordance with example embodiments;

FIG. 5A illustrates a top view of a 3D decoupling semiconductor capacitor in accordance with example embodiments;

FIG. 5B illustrates a cross-sectional view of the 3D decoupling semiconductor capacitor of FIG. 5A;

FIGS. 5C and 5D illustrate top views of 3D decoupling semiconductor capacitors in accordance with example embodiments;

FIG. 6A illustrates a top view of a semiconductor package in accordance with example embodiments;

FIG. 6B illustrates an internal side view of the semiconductor package of FIG. 6A;

FIGS. 7A to 7E illustrate top views and internal side views of semiconductor packages in accordance with example embodiments;

FIG. 8A illustrates a top view of a semiconductor package in accordance with example embodiments;

FIG. 8B illustrates an internal side view of the semiconductor package of FIG. 8A;

FIG. 9 illustrates a partial top view illustrating a connection state of a semiconductor package in accordance with example embodiments;

FIG. 10A illustrates a schematic view illustrating a semiconductor module in accordance with example embodiments;

FIG. 10B illustrates a schematic view illustrating an electronic system in accordance with example embodiments; and

FIG. 10C illustrates a schematic view illustrating a storage device in accordance with example embodiments.

### DETAILED DESCRIPTION

Example embodiments will now be described more fully hereinafter with reference to the accompanying drawings; however, they may be embodied in different forms and should not be construed as limited to the example embodiments set forth herein. Rather, these example embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “on,” “connected to,” or “coupled to” another element or layer, it can be directly on, connected, or coupled to the other element or layer, or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present disclosure.

Spatially relative terms, such as “beneath,” “below,” “lower,” “above,” “upper,” and the like may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized structures (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “electrically connected” and/or “electrically insulated” used in this specification, specify “directly connected or insulated.”

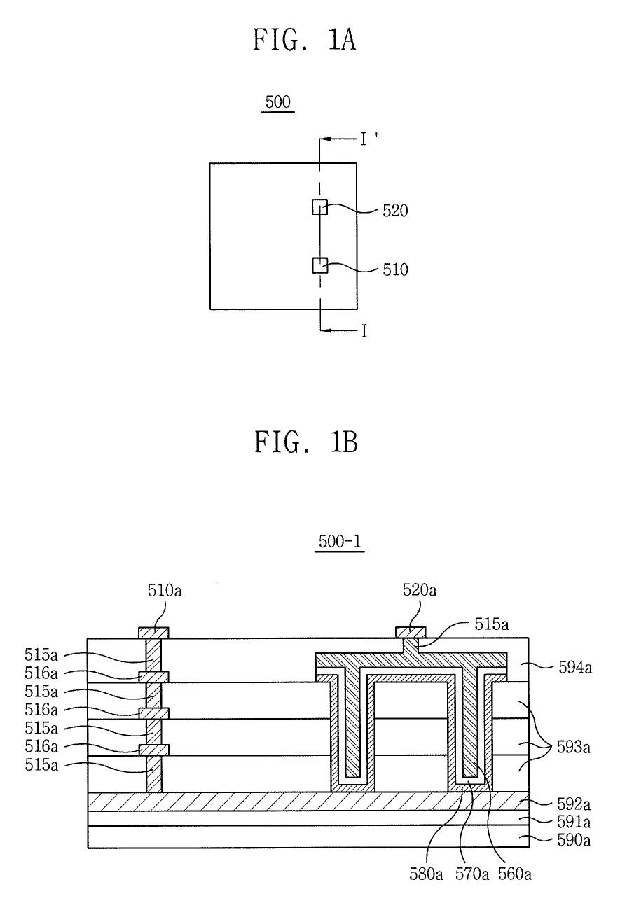

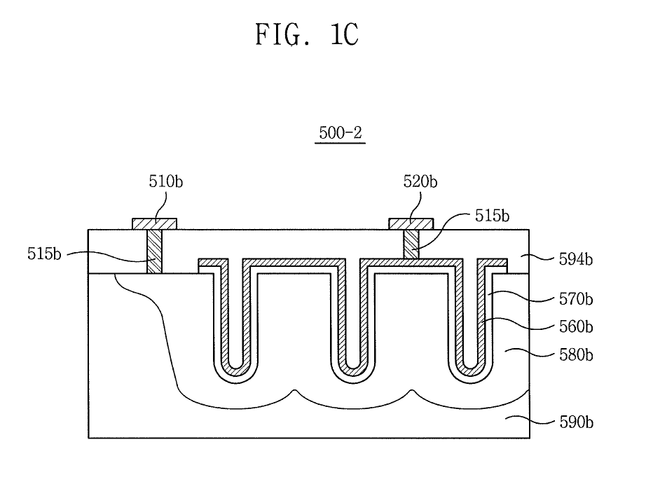

FIG. 1A illustrates a schematic top view of a three-dimensional (3D) decoupling semiconductor capacitor in accordance with first and second example embodiments. FIGS. 1B and 1C illustrate schematic cross-sectional views of the 3D decoupling semiconductor capacitor taken along line I-P of FIG. 1A.

The 3D capacitor may be a capacitor that includes a trench-type electrode. A semiconductor capacitor may be a capacitor fabricated by processing a silicon wafer using a semiconductor process. Herein, the term “3D capacitor” or “semiconductor capacitor” may be simplified as the term “capacitor,” and the term “decoupling capacitor” in the specification may be regarded as “3D decoupling capacitor,” “decoupling semiconductor capacitor,” or “3D decoupling semiconductor capacitor.”

Referring to FIGS. 1A and 1B, a 3D decoupling semiconductor capacitor 500-1 according to the first example embodiment may include a capacitor substrate 590a. The capacitor substrate 590a may include a silicon wafer. A first insulating layer 591a may be formed on the capacitor substrate 590a and a metal layer 592a may be formed on the first insulating layer 591a. A second insulating layer 593a may be formed on the metal layer 592a. A hole or trench may be formed to expose an upper surface of the metal layer 592a and a side surface of the second insulating layer 593a.

A lower electrode 580a may be formed on an inner surface of the hole or trench and a portion of an upper surface of the second insulating layer 593a. A dielectric layer 570a may be formed on the lower electrode 580a. The lower electrode 580a and the dielectric layer 570a may be formed in a hole or trench shape. Subsequently, an upper electrode 560a may be formed on the dielectric layer 570a to be filled within the hole or trench. The lower electrode 580a and the upper electrode 560a may include a metal or a metal silicide.

A third insulating layer 594a may be formed on the upper electrode 560a. A first capacitor pad 510a and a second capacitor pad 520a may be formed on the third insulating layer 594a. The first capacitor pad 510a may be electrically connected to the metal layer 592a or the lower electrode 580a via plugs 515a and via pads 516a. The second capacitor pad 520a may be electrically connected to the upper electrode 560a. The via plugs 515a and the via pads 516a may pass through the second insulating layer 593a and the third insulating layer 594a to connect the first capacitor pad 510a to the metal layer 592a or the lower electrode 580a. Terms and functions of the first capacitor pad 510a and the second capacitor pad 520a may be mutually exchanged.

Referring to FIGS. 1A and 1C, a decoupling semiconductor capacitor 500-2 according to the second example embodiment may include a capacitor substrate 590b and a capacitor structure formed on the capacitor substrate 590b. The capacitor substrate 590b may include a silicon wafer. The capacitor substrate 590b may include a hole or trench. The capacitor structure may include a lower electrode 580b formed in a portion of the capacitor substrate adjacent to an inner surface of the hole or trench, a dielectric layer 570b conformally formed on the lower electrode 580b, an upper electrode 560b formed on the dielectric layer 570b, and capacitor pads 510b and 520b. The lower electrode 580b may be a portion of the capacitor substrate 590b including N-type impurity ions. The lower electrode 580b may be a layer formed on the inner surface of the hole or trench. The dielectric layer 570b may be formed on the inner surface of the hole or trench. The dielectric layer 570b may include an insulating material including silicon oxide, silicon nitride, metal oxide, etc. The upper electrode 560b may include silicon including N-type impurity ions. An insulating layer 594b may be formed on the capacitor substrate 590b and the upper electrode 560b. The first capacitor pad 510b electrically connected to the lower electrode 580b, and the second capacitor pad 520b electrically connected to the upper electrode 560b, may be formed on the insulating layer 594b. The first and second capacitor pads 510b and 520b may be electrically connected to the lower electrode 580b and the upper electrode 560b via conductive via plugs 515b, respectively.

Elements having the same functions in FIGS. 1B and 1C will be described below with a same reference number.

The first capacitor pad 510 and the second capacitor pad 520 may be electrically connected to input/output (I/O) pads of a semiconductor chip, the I/O pads transferring a power supply voltage (power) or a ground voltage, respectively. In addition, each of the first capacitor pad 510 and the second capacitor pad 520 formed on the decoupling semiconductor capacitor 500 may be plural in number.

The decoupling semiconductor capacitor 500 may be fabricated using a conventional semiconductor process and thus formed in a small size. In addition, a bottom surface of the capacitor substrate 590 may be ground down to lower the overall height of the decoupling semiconductor capacitor 500. Accordingly, a size of the semiconductor package may be reduced by employing the decoupling semiconductor capacitor 500.

By way of comparison, in a semiconductor package that employs a multilayer ceramic capacitor (MLCC), the MLCC may have to be mounded directly on the packaging substrate. In contrast, the decoupling semiconductor capacitor 500 has a small size and high capacitance, and thus can be diversely mounted in the semiconductor package.

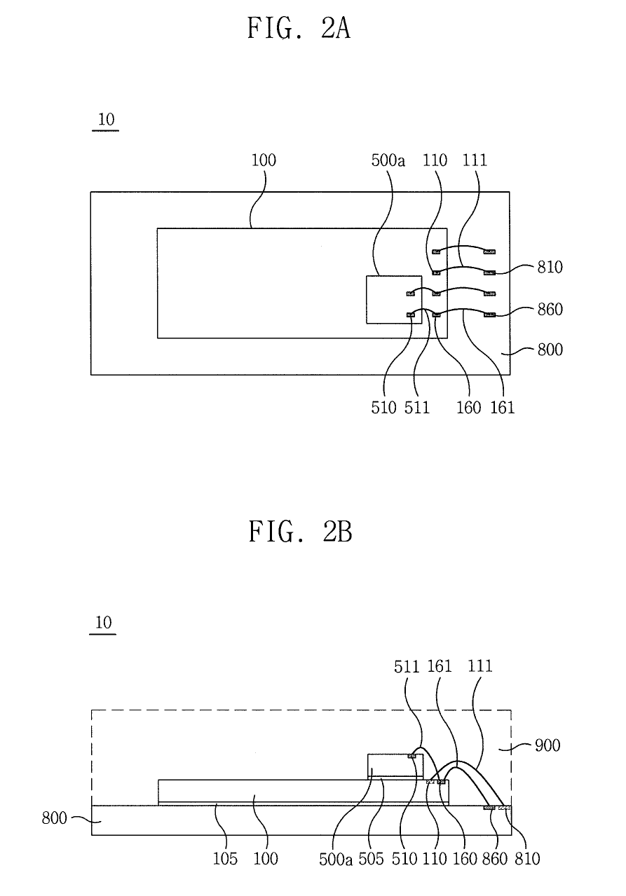

FIGS. 2A and 2B illustrate a schematic top view and an internal side view of a semiconductor package in accordance with example embodiments. Specifically, a semiconductor package in which one semiconductor chip is mounted on a packaging substrate and a decoupling semiconductor capacitor is mounted on the semiconductor chip is illustrated. FIG. 2A illustrates the top view of the semiconductor package in which the decoupling semiconductor capacitor is electrically connected to the semiconductor chip via a bonding wire, and FIG. 2B illustrates the internal side view of the semiconductor package.

Referring to FIGS. 2A and 2B, a semiconductor package 10 according to the present example embodiment may include a packaging substrate 800, a semiconductor chip 100 mounted on the packaging substrate 800, and a decoupling semiconductor capacitor 500a electrically connected to the semiconductor chip 100.

The packaging substrate 800 may include first bond fingers 810 and second bond fingers 860. The first and second bond fingers 810 and 860 may be formed along one side edge of the packaging substrate 800. The semiconductor chip 100 may include first chip pads 110 and second chip pads 160. In addition, the decoupling semiconductor capacitor 500a may include capacitor pads 510. Herein, the packaging substrate 800 may include, e.g., a rigid printed circuit board (PCB), a flexible PCB, a rigid flexible PCB, a tape distribution substrate, a ceramic substrate, and a combination thereof.

The first and second bond fingers 810 and 860, the first and second chip pads 110 and 160, and the capacitor pads 510 may include a conductive material. For example, the first and second bond fingers 810 and 860, the first and second chip pads 110 and 160, and the capacitor pads 510 may include a metal such as Au, Ag, Cu, Ni, Al, Sn, Pb, Pt, Bi, and/or In. In addition, the first and second bond fingers 810 and 860, the first and second chip pads 110 and 160, and the capacitor pads 510 may be buried in upper surfaces of the packaging substrate 800, the semiconductor chip 100, and the decoupling semiconductor capacitor 500a respectively, or may protrude from the upper surfaces of the packaging substrate 800, the semiconductor chip 100, and the decoupling semiconductor capacitor 500a respectively.

The first chip pad 110 may transfer a signal of the semiconductor chip 100, and the second chip pad 160 may transfer a power supply voltage or a ground voltage in the semiconductor chip 100.

The first chip pads 110 may be electrically connected to the first bond fingers 810. For example, the first chip pads 110 may be electrically connected to the first bond fingers 810 via first bonding wires 111, as illustrated in FIGS. 2A and 2B. The second chip pads 160 may be electrically connected to the second bond fingers 860 via second bonding wires 161.

Referring to FIG. 2B, the second bond fingers 860 may overlap the first bond fingers 810, and thus the first bond fingers 810 are illustrated using lighter shading in FIG. 2B. Likewise, the second chip pads 160 of the semiconductor chip 100 overlap the first chip pads 110, and thus the first chip pads 110 are illustrated using lighter shading in FIG. 2B. That is, for better understanding in FIG. 2B and in the following internal side views, one of the first and second bond fingers 810 and 860 which is overlapped by the other, and one of the chip pads 110 and 160 that is overlapped by the other, are indicated by lighter shading in order to show an electric connection by bonding wires.

The second chip pads 160 may be electrically connected to the capacitor pads 510. For example, as illustrated in FIGS. 2A and 2B, the second chip pads 160 may be electrically connected to the capacitor pads 510 by third bonding wires 511. Some of the capacitor pads 510 may be electrically connected to an upper electrode in the decoupling semiconductor capacitor 500a, and others of the capacitor pads 510 may be electrically connected to a lower electrode in the decoupling semiconductor capacitor 500a.

The first and second chip pads 110 and 160 may be I/O pads. The first and second chip pads 110 and 160 may be redistribution pads. That is, the first and second chip pads 110 and 160 may be formed by a redistribution process to minimize a distance between the first and second chip pads 110 and 160 and the capacitor pads 510, and minimize a distance between the first and second chip pads 110 and 160 and the first and second bond fingers 810 and 860. For example, the first and second chip pads 110 and 160 may be formed along an edge of the upper surface of the semiconductor chip 100.

In addition, in the top view as illustrated in FIG. 2A, the decoupling semiconductor capacitor 500a may be mounted on the semiconductor chip 100 such that the first and second chip pads 110 and 160 are disposed between the capacitor pads 510, on one side, and the bond fingers 810 and 860, on the other side.

When the semiconductor chip 100, the packaging substrate 800, and the decoupling semiconductor capacitor 500a are connected by bonding wires, it may be desirable to make the bonding wires as short as possible, which is advantageous to a fabrication process. Further, inductance from connections to the decoupling semiconductor capacitor 500a may be minimized to improve performance of the semiconductor package 10.

The semiconductor chip 100 may include, e.g., a memory chip inputting or outputting signals at high speed. For example, the semiconductor chip 100 may include a dynamic random access memory (DRAM) chip.

In an implementation, the semiconductor chip 100 may be in direct contact with the packaging substrate 800, and the decoupling semiconductor capacitor 500a may be in direct contact with the semiconductor chip 100. In another implementation, the semiconductor chip 100 and the decoupling semiconductor capacitor 500a may include adhesion layers 105 and 505 on bottom surfaces thereof, respectively. The adhesion layers 105 and 505 may include, e.g., a non-conductive film (NCF), an anisotropic conductive film (ACF), a die attaching film (DAF), a non-conductive paste (NCP), or a combination thereof.

The semiconductor package 10 may include an encapsulant 900 as indicated by a dotted line of FIG. 2B. The encapsulant 900 may be used to protect the semiconductor chip 100, the decoupling semiconductor capacitor 500a, and the bonding wires 111, 161, and 511 from an external shock. For example, the encapsulant 900 may include an epoxy molding compound (EMC). The encapsulant 900 may be formed by an injection molding process.

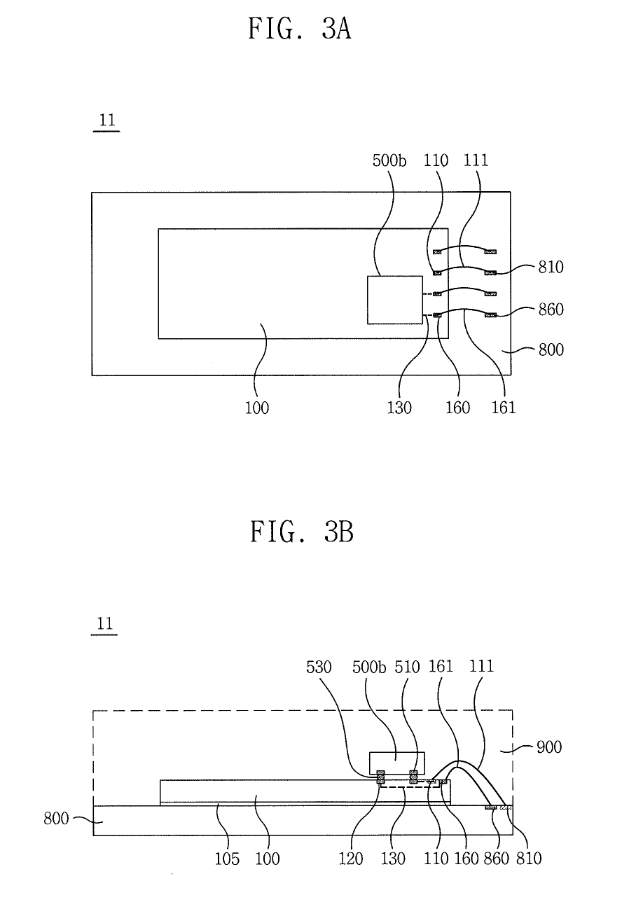

FIG. 3A illustrates a top view of a semiconductor package 11 in which a decoupling semiconductor capacitor 500b is electrically connected to a semiconductor chip 100 by a flip chip bonding method, and FIG. 3B illustrates an internal side view of the semiconductor package 11. Description of portions of the semiconductor package 11 that are the same as those of the semiconductor package 10 as illustrated in FIGS. 2A and 2B will be omitted. Accordingly, unless mentioned otherwise, the description of the semiconductor package 10 as illustrated in FIGS. 2A and 2B may be applied as is.

Referring to FIGS. 3A and 3B, the semiconductor package 11 according to the present example embodiment may include a packaging substrate 800, a semiconductor chip 100 mounted on the packaging substrate 800, and a decoupling semiconductor capacitor 500b mounted on and connected to the semiconductor chip 100.

The decoupling semiconductor capacitor 500b may be electrically connected to the semiconductor chip 100 by a flip chip bonding method. For example, conductive lands 120 for flip chip bonding may be formed on an upper surface of the semiconductor chip 100. An upper electrode or a lower electrode of the decoupling semiconductor capacitor 500b may be electrically connected to the lands 120 via conductive materials 530 and the conductive materials 530 may be electrically connected to the capacitor pads 510. The conductive material 530 may be, e.g., a solder connection such as a solder ball type bump.

The lands 120 may be electrically connected to second chip pads 160 of the semiconductor chip 100 by distribution lines 130 formed in the semiconductor chip 100, as indicated by dotted lines of FIGS. 3A and 3B. For example, the distribution line 130 may be a distribution line that is formed in a redistribution layer buried in the semiconductor chip 100. The distribution line 130 may be an exposed distribution line formed on an upper surface of the semiconductor chip 100. In this case, an active surface of the decoupling semiconductor capacitor 500b (i.e., an upper surface during fabrication of the decoupling semiconductor capacitor 500b) may face toward the semiconductor chip 100.

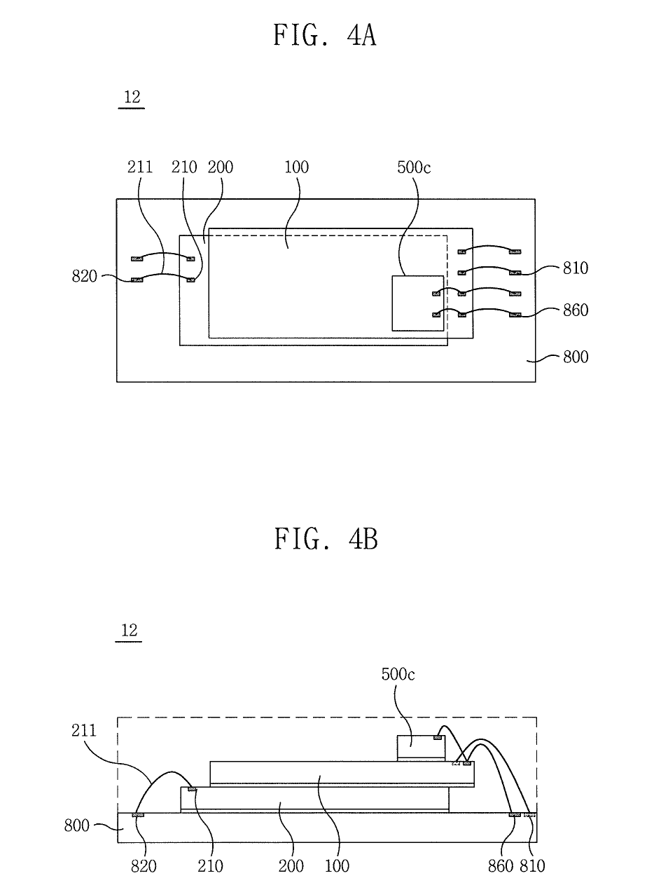

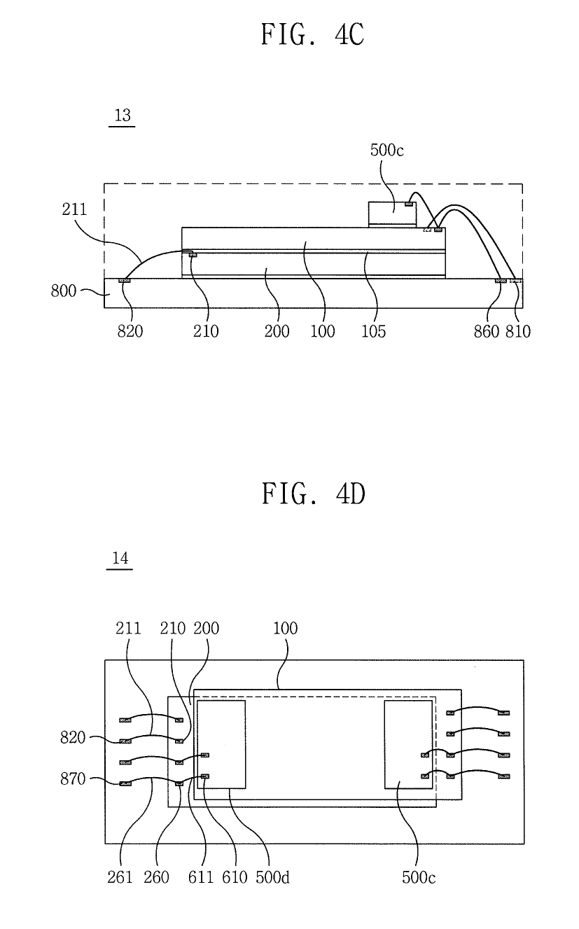

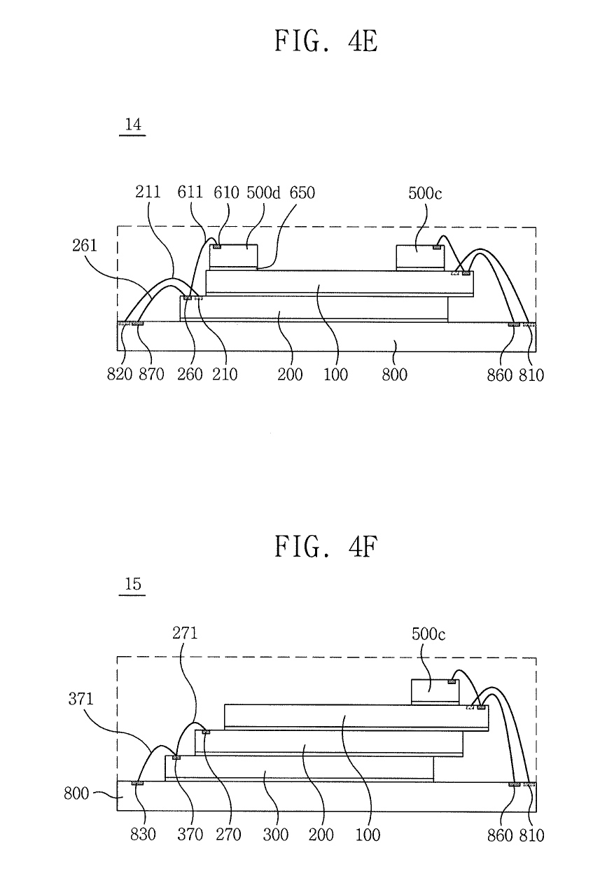

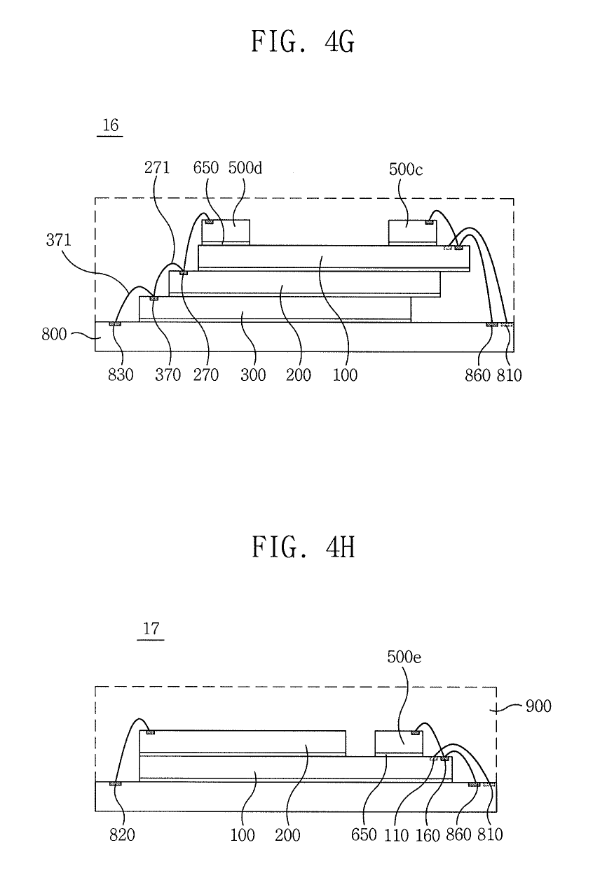

FIGS. 4A to 4E illustrate semiconductor packages in which one or more other semiconductor chips are mounted between the semiconductor chip 100 and the packaging substrate 800 of the semiconductor packages 10 and 11 of FIGS. 2A to 3B according to the present example embodiment.

Referring to FIGS. 4A and 4B, a semiconductor package 12 according to the present example embodiment may include a packaging substrate 800, a second semiconductor chip 200 and a first semiconductor chip 100 stacked on the packaging substrate 800, and a first decoupling semiconductor capacitor 500c electrically connected to the first semiconductor chip 100. The semiconductor chip 100 and the decoupling semiconductor capacitor 500c may be electrically connected by a wire bonding method, as illustrated in FIGS. 2A and 2B, or by a flip chip bonding method, as illustrated in FIGS. 3A and 3B. Accordingly, description of portions of the semiconductor package 12 which are the same as those of the semiconductor packages 10 and 11 as illustrated in FIGS. 2A to 3B will be omitted. Unless mentioned otherwise, the description of the semiconductor packages 10 and 11 as illustrated in FIGS. 2A to 3B may be applied as is. FIGS. 4A and 4B illustrate the semiconductor package 12 in which the first semiconductor chip 100 and the first decoupling semiconductor capacitor 500c are electrically connected by a wire bonding method.

The packaging substrate 800 may include first bond fingers 810, second bond fingers 860, and third bond fingers 820 formed along opposing side edges of an upper surface of the packaging substrate 800. The third bond fingers 820 may be formed in the opposite side of the first and second bond fingers 810 and 860. The second semiconductor chip 200 may be mounted on the packaging substrate 800 between the first and third bond fingers 810 and 820, and the first semiconductor chip 100 may be stacked on the second semiconductor chip 200. The first semiconductor chip 100 may be stacked in a cascade or step to expose a third chip pads 210 included in the second semiconductor chip 200, as illustrated in FIG. 4B.

The second semiconductor chip 200 may include the third chip pads 210 formed of a conductive material on an upper surface thereof. The third chip pad 210 may include a terminal serving as a signal I/O pin of the second semiconductor chip 200. The third chip pads 210 and the third bond fingers 820 may be electrically connected by fourth bonding wires 211.

Various stacking arrangements of the second semiconductor chip 200 and the first semiconductor chip 100 may be used. Although FIGS. 4A and 4B illustrate the first and second semiconductor chips 100 and 200 stacked in a cascade, a first semiconductor chip 100 and a second semiconductor chip 200 may be vertically aligned, as in a semiconductor package 13 illustrated in FIG. 4C. In this case, the fourth bonding wires 211 may be buried in an adhesion layer 105 (disposed on a bottom surface of the first semiconductor chip 100) to electrically connect the third bond fingers 820 and the third chip pads 210.

As illustrated in FIGS. 4A to 4C, the second semiconductor chip 200 may not be electrically connected to the decoupling semiconductor capacitor 500c. For example, such an arrangement may be used in the case that the second semiconductor chip 200 is a flash memory chip.

Generally, the decoupling semiconductor capacitor may be connected to the semiconductor chip in order to prevent voltage swing due to a switching noise occurring at a ground surface and a power supply terminal by a high speed simultaneous switching of an integrated circuit. A memory with a high data processing speed may be connected to the decoupling semiconductor capacitor to improve performance.

FIGS. 4D and 4E illustrate a semiconductor package 14 in which a second semiconductor chip 200 is electrically connected to an additional (second) decoupling semiconductor capacitor 500d.

Referring to FIGS. 4D and 4E, the second decoupling semiconductor capacitor 500d may be in direct contact with the first semiconductor chip 100 or may be mounted on the first semiconductor chip 100 via an adhesion layer 650.

The second decoupling semiconductor capacitor 500d may be implemented using any of the decoupling semiconductor capacitors 500, 500-1, and 500-2 illustrated in FIGS. 1A to 1C. The second decoupling semiconductor capacitor 500d may include second capacitor pads 610. A packaging substrate 800 may further include fourth bond fingers 870. In addition, the second semiconductor chip 200 may include third chip pads 210 having terminals serving as signal pins, and may include fourth chip pads 260 having terminals serving as power/ground pins.

The fourth chip pads 260 may be electrically connected to the second capacitor pads 610 via fifth bonding wires 611 and, at the same time, may be electrically connected to the fourth bond fingers 870 via sixth bonding wires 261.

In the semiconductor package 14 illustrated in FIGS. 4D and 4E, the first and second decoupling semiconductor capacitors 500c and 500d are disposed on the uppermost semiconductor chip 100 to embody a semiconductor package, the size of which is not significantly affected by mounting of the first and second decoupling semiconductor capacitors 500c and 500d.

FIG. 4F illustrates an internal side view of a semiconductor package 15, in which two semiconductor chips 200 and 300 are mounted between a first semiconductor chip 100 and a packaging substrate 800. The respective semiconductor chips 100, 200, and 300 may be stacked in a cascade to expose chip pads of each lower semiconductor chip. The first semiconductor chip 100 and a first decoupling semiconductor capacitor 500c may be electrically connected by a wire bonding method or a flip chip bonding method, as illustrated in FIGS. 2A to 3B. FIG. 4F illustrates an electrical connection by a wire bonding method and description of the electrical connection which is the same as that of the semiconductor package 10 as illustrated in FIGS. 2A and 2B will be omitted.

The second semiconductor chip 200 and the third semiconductor chip 300 may not be electrically connected to the first decoupling semiconductor capacitor 500c. In this case, chip pads 270 of the second semiconductor chips 200 and chip pads 370 of the third semiconductor chips 300 may be directly and electrically connected to bond fingers 830 formed on a packaging substrate 800 via bonding wires 271 and 371, respectively. In another implementation, as illustrated in FIG. 4F, the chip pads 270 of the second semiconductor chip 200 may be electrically connected to the chip pads 370 of the third semiconductor chip 300 by bonding wires 271, and the chip pads 370 of the third semiconductor chip 300 may be electrically connected to the bond fingers 830 by the bonding wires 371. Although FIG. 4F illustrates two semiconductor chips 200 and 300 stacked below the first semiconductor chip 100, more than two semiconductor chips may be stacked.

FIG. 4G illustrates an internal side view of a semiconductor package 16, in which a plurality of semiconductor chips 200 and 300 are stacked between a first semiconductor chip 100 and a packaging substrate 800, and all or some of the plurality of semiconductor chips 200 and 300 are electrically connected to a second decoupling semiconductor capacitor 500d. The first semiconductor chip 100 and a first decoupling semiconductor chip 500c may be electrically connected by a wire bonding method or a flip chip bonding method, as illustrated in FIGS. 2A to 3B.

Referring to FIG. 4G, the second semiconductor chip 200 may be electrically connected to the second decoupling semiconductor capacitor 500d, and the second decoupling semiconductor capacitor 500d may be mounted on the first semiconductor chip 100. The second decoupling semiconductor capacitor 500d may be in direct contact with the first semiconductor chip 100 or in contact with the first semiconductor chip 100 via an adhesion layer 650.

The three semiconductor chips 100, 200, and 300 may be sequentially stacked on the packaging substrate 800 in a cascade. The third semiconductor chip 300 may include chip pads 370 that are electrically connected to bond fingers 830 formed on the packaging substrate 800 by bonding wires 371. The second semiconductor chip 200 may include chip pads 270 that are electrically connected to the chip pads 370 of the third semiconductor chip 300 by bonding wires 271.

Referring to FIG. 4H, a semiconductor package 17 according to an example embodiment may include a packaging substrate 800, a first semiconductor chip 100, and a second semiconductor chip 200 sequentially stacked on the packaging substrate 800, and a decoupling semiconductor capacitor 500e electrically connected to the first semiconductor chip 100.

The second semiconductor chip 200 and the decoupling semiconductor capacitor 500e may be mounted in direct contact with the first semiconductor chip 100 or in contact with the first semiconductor chip 100 via an adhesion layer 650. The first semiconductor chip 100 and the decoupling semiconductor capacitor 500e may be electrically connected by a wire bonding method or a flip chip bonding method. In the case of the wire bonding method, the description of the semiconductor package 10 as illustrated in FIGS. 2A and 2B may be applied as is. In the case of the flip chip bonding method, the description of the semiconductor package 11 as illustrated in FIGS. 3A and 3B may be applied as is.

Mounting of the decoupling semiconductor capacitor 500e may not cause a significant increase in the size or height of the semiconductor package 17. Ultimately, this helps enable high integration and miniaturization of the semiconductor package 17.

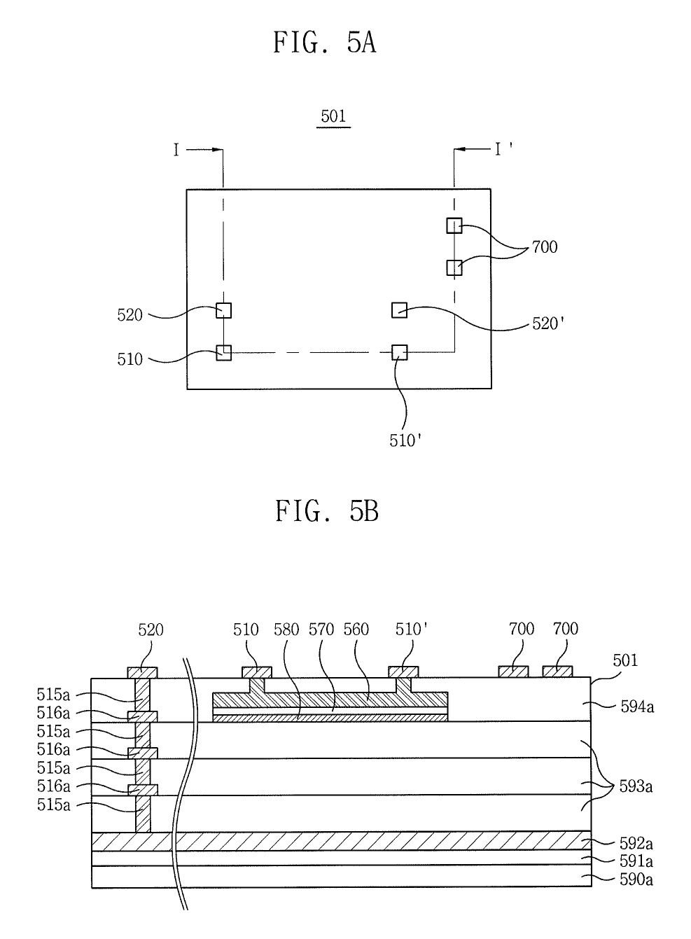

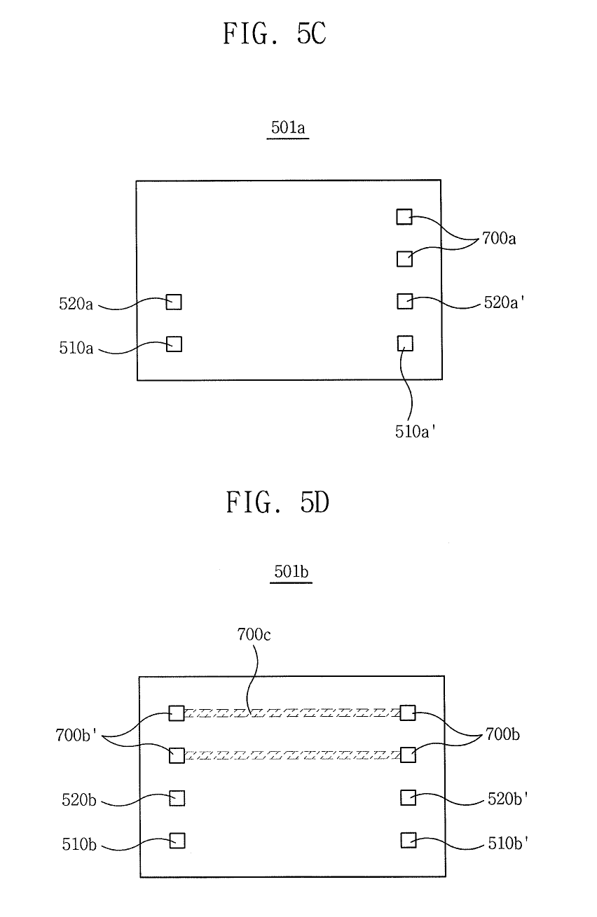

FIG. 5A illustrates a schematic top view of a decoupling semiconductor capacitor 501 according to example embodiments, and FIG. 5B illustrates a cross-sectional view of the decoupling semiconductor capacitor 501 taken along line I-P of FIG. 5A. Unless mentioned otherwise, the description of the decoupling semiconductor capacitor 500 as illustrated in FIGS. 1A to 1C may be applied as is, and description of portions of the decoupling semiconductor capacitor 501 that are the same as those of the decoupling semiconductor capacitor 500 as illustrated in FIGS. 1A to 1C will be omitted.

Referring to FIGS. 5A and 5B, the decoupling semiconductor capacitor 501 may include first capacitor pads 510, second capacitor pads 510′, and third capacitor pads 700. The third capacitor pads 700 may be formed along an edge of an upper surface of the decoupling semiconductor capacitor (501). The third capacitor pads 700 may be dummy pads that are insulated from conductive materials inside or outside the decoupling semiconductor capacitor 501. The third capacitor pads 700 may include a conductive material. For example, the third capacitor pads 700 may include a metal such as Au, Ag, Cu, Ni, Al, Sn, Pb, Pt, Bi, and/or In. The third capacitor pads 700 may serve as a connection point of a bonding wire electrically connecting a chip pad serving as a signal I/O pin of a semiconductor chip and a packaging substrate, as described below.

The first capacitor pads 510 and the second capacitor pads 510′ may be directly connected by bonding wires. The first capacitor pads 510 and the second capacitor pads 510′ may be electrically connected by an upper electrode 560 within the decoupling semiconductor capacitor 501 in order to minimize an effect of inductance caused by the decoupling semiconductor capacitor 501. Fourth capacitor pads 520 and fifth capacitor pads 520′ may be electrically connected to each other. Although not shown in the drawings, the fourth capacitor pads 520 and the fifth capacitor pads 520′ may be electrically connected via a lower electrode 580, a metal layer 592a, via plugs 515a, and/or via pads 516a.

FIG. 5C illustrates a top view of a decoupling semiconductor capacitor 501a according to other example embodiments. Referring to FIG. 5C, third capacitor pads 700a, second capacitor pads 510a′, and fifth capacitor pads 520a′ may be aligned in a line on an upper surface of the decoupling semiconductor capacitor 501a in order to easily perform a capillary process forming a bonding wire.

FIG. 5D illustrates a top view of a decoupling semiconductor capacitor 501b according to another example embodiment. The decoupling semiconductor capacitor 501b may include third capacitor pads 700b formed along one side edge of an upper surface thereof and sixth capacitor pads 700b′ formed along an opposite side edge of the upper surface thereof. Signal I/O terminals of a semiconductor chip electrically connected to the decoupling semiconductor capacitor 501b may be electrically connected to the third capacitor pads 700b by bonding wires, and some of bond fingers of a packaging substrate may be electrically connected to the sixth capacitor pads 700b′ by bonding wires. The third capacitor pads 700b and the sixth capacitor pads 700′ may be electrically connected by distribution lines 700c formed of a conductive material within the decoupling semiconductor capacitor 501b, or on an upper surface of the decoupling semiconductor capacitor 501b, as indicated by dotted lines. In comparison with the case where the bond fingers formed on the packaging substrate are directly connected to the third capacitor pads 700b by the bonding wires, the decoupling semiconductor capacitor 501b of FIG. 5D may be used to minimize an effect of inductance caused by the decoupling semiconductor capacitor 501b and the length of the bonding wire. The sixth capacitor pads 700b′ may be horizontally aligned with first capacitor pads 510b and the second capacitor pads 520b. The third capacitor pad 700b and the sixth capacitor pad 700b′ are electrically connected and may be regarded as one capacitor pad. In this case, the third capacitor pad 700b and the sixth capacitor pad 700b′ may be regarded as a first edge portion and a second edge portion, respectively.

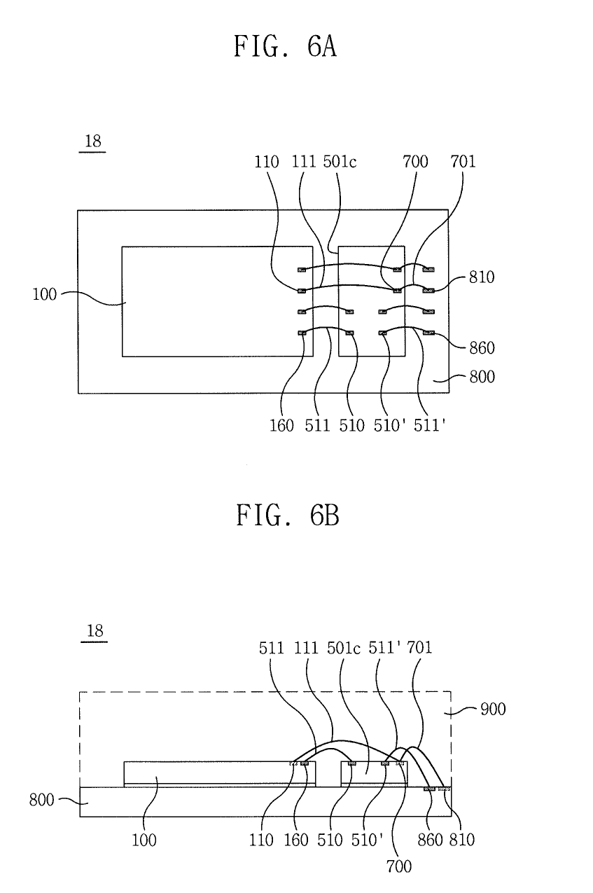

FIG. 6A illustrates a top view of a semiconductor package 18 according to an example embodiment, and FIG. 6B illustrates an internal side view of the semiconductor package 18.

Referring to FIGS. 6A and 6B, the semiconductor package 18 may include a packaging substrate 800, a semiconductor chip 100 mounted on the packaging substrate 800, and a decoupling semiconductor capacitor 501c mounted on the packaging substrate 800. The packaging substrate 800 may include first bond fingers 810 and second bond fingers 860 on one side edge thereof, and the semiconductor chip 100 may include first chip pads 110 and second chip pads 160.

The decoupling semiconductor capacitor 501c may be implemented using any of the decoupling semiconductor capacitors 501, 501a and 501b illustrated in FIGS. 5A to 5C. The decoupling semiconductor capacitor 501c may be disposed between the bond fingers 810 and 860 and the semiconductor chip 100. The decoupling semiconductor capacitor 501c may be disposed to be in direct contact with the packaging substrate 800, or in contact with the packaging substrate 800 via an adhesion layer formed on a bottom surface of the decoupling semiconductor capacitor 501c.

The first chip pads 110 may be electrically connected to third capacitor pads 700 by first bonding wires 111. The third capacitor pads 700 may be electrically connected to the first bond finger 810 by second bonding wires 701.

The second chip pads 160 of the semiconductor chip 100 may be electrically connected to first capacitor pads 510 by third bonding wires 511, and second capacitor pads 510′ may be electrically connected to the second bond fingers 860 by fourth bonding wires 511′. The first capacitor pads 510 and the second capacitor pads 510′ may be electrically connected by an upper electrode formed within the decoupling semiconductor capacitor 501c.

In the case that the first chip pads 110 and the first bond fingers 810 are directly connected by bonding wires, the bonding wires may be configured to pass over the decoupling semiconductor capacitor 501c disposed between the semiconductor chip 100 and the first bond fingers 810. In this case, the bonding wires may be lengthened, which may reduce reliability of a device, e.g., by increasing of inductance or resistance, or causing the bonding wires to be in contact with a corner of the decoupling semiconductor capacitor 501c. Thus, the third capacitor pads 700 may be formed on an edge of an upper surface of the decoupling semiconductor capacitor 501c to provide connection points of bonding wires that electrically connect the first capacitor pads 110 and the first bond fingers 810.

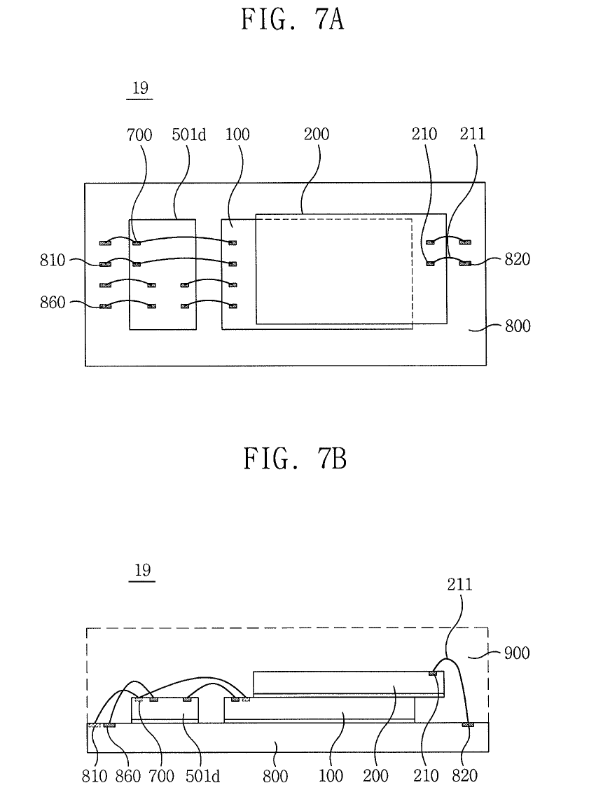

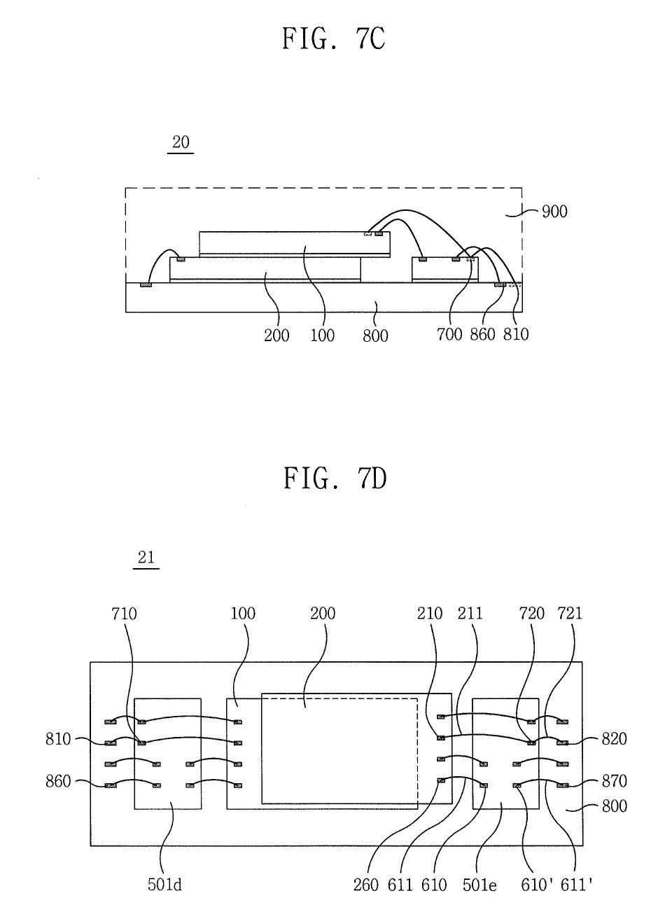

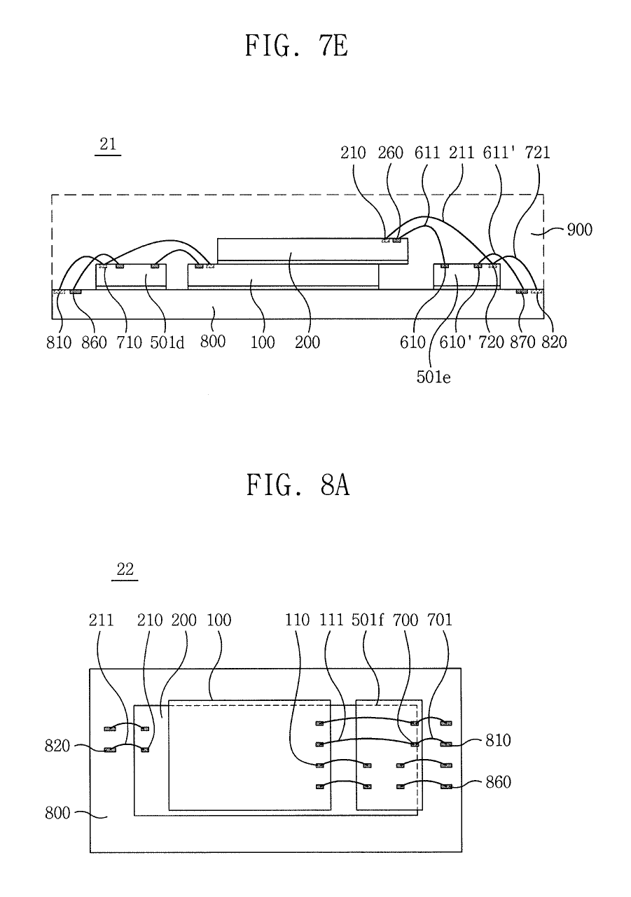

FIGS. 7A to 7E illustrate semiconductor packages in which one or more semiconductor chips are further mounted on the semiconductor chip 100, or between the semiconductor chip 100 and the packaging substrate 800 in the semiconductor package 18 of FIGS. 6A and 6B, according to the present example embodiment. For example, each of the semiconductor packages according to the example embodiments may include a packaging substrate 800, and a first semiconductor chip 100 and a second semiconductor chip 200 stacked on the packaging substrate 800. The second semiconductor chip 200 may be mounted between the first semiconductor chip 100 and the packaging substrate 800, or on the first semiconductor chip 100. Description of portions of the semiconductor packages which are the same as those of the semiconductor package 18 as illustrated in FIGS. 6A to 6C will be omitted. Accordingly, unless mentioned otherwise, the description of the semiconductor package 18 as illustrated in FIGS. 6A to 6C may be applied as is.

FIG. 7A illustrates a top view of a semiconductor package 19 that includes the packaging substrate 800, the first semiconductor chip 100 mounted on the packaging substrate 800, the second semiconductor chip 200 mounted on the first semiconductor chip 100, and a first decoupling semiconductor capacitor 501d mounted on the packaging substrate 800 and electrically connected to the first semiconductor chip 100. FIG. 7B illustrates an internal side view of the semiconductor package 19.

Referring to FIGS. 7A and 7B, the packaging substrate 800 may include first bond fingers 810, second bond fingers 860, and third bond fingers 820 formed along both side edges of an upper surface thereof. The first semiconductor chip 100 and the second semiconductor chip 200 may be sequentially stacked between the first bond finger 810 and the third bond finger 820. The semiconductor chips 100 and 200 may be stacked in a cascade to expose chip pads of the first semiconductor chip 100. In other implementations, arrangements different from the illustrated stacking structure may be used.

The decoupling semiconductor capacitor 501d electrically connected to the first semiconductor chip 100 may be mounted between the first bond fingers 810 and the first semiconductor chip 100. The decoupling semiconductor capacitor 501d may be in direct contact with the packaging substrate 800, or in contact with the packaging substrate 800 via an adhesion layer. The decoupling semiconductor capacitor 501d may include third capacitor pads 700 on an upper surface thereof. Description of an electrical connection between the decoupling semiconductor capacitor 501d and the first semiconductor chip 100 is the same as that of the semiconductor package 18 of FIGS. 6A and 6B.

The second semiconductor chip 200 may include third chip pads 210 including terminals serving as signal pins. The third chip pads 210 may be electrically connected to the third bond fingers 820, for example, by bonding wires 211. The second semiconductor chip 200 may be, e.g., a flash memory chip.

FIG. 7C illustrates a semiconductor package 20 in which the second semiconductor chip 200 is mounted between the first semiconductor chip 100 and the packaging substrate 800. Description of electrical connections between the second semiconductor chip 200 and the packaging substrate 800 and between the first semiconductor chip 100 and the packaging substrate 800 is the same as that of the semiconductor package 19 of FIGS. 7A and 7B.

FIGS. 7D and 7E illustrate a semiconductor package 21 that also includes a second decoupling semiconductor capacitor 501e electrically connected to the second semiconductor chip 200. The second semiconductor chip 200 may be mounted between the first semiconductor chip 100 and the packaging substrate 800, or on the first semiconductor chip 100. For convenience, the case in which the second semiconductor chip 200 is mounted on the first semiconductor chip 100 will be described as an example.

Referring to FIGS. 7D and 7E, the semiconductor package 21 may include the packaging substrate 800 including first to fourth bond fingers 810, 820, 860, and 870, the first and second semiconductor chips 100 and 200 sequentially stacked on the packaging substrate 800, and the first and second decoupling semiconductor capacitors 501d and 501e mounted on the packaging substrate 800 and in direct contact with the packaging substrate 800 or in contact with the packaging substrate 800 via adhesion layers. The first decoupling semiconductor capacitor 501d may be electrically connected to the first semiconductor chip 100, and the second decoupling semiconductor capacitor 501e may be electrically connected to the second semiconductor chip 200. The first semiconductor chip 100 and the second semiconductor chip 200 may be stacked in a cascade. In other implementations, arrangements different from the illustrated stacking structure may be used.

The first and second bond fingers 810 and 860 may be formed along one side edge of the packaging substrate 800, and the third and fourth bond fingers 820 and 870 may be formed along an opposite side edge of the packaging substrate 800. The first decoupling semiconductor capacitor 501d may be disposed between the first semiconductor chip 100 and the first and second bond fingers 810 and 860. Likewise, the second decoupling semiconductor capacitor 501e may be disposed between the second semiconductor chip 200 and the third and fourth bond fingers 820 and 870.

As described above, the second decoupling semiconductor capacitor 501e may be a decoupling semiconductor capacitor including a dielectric layer formed in a trench shape. The second decoupling semiconductor capacitor 501e may include fourth capacitor pads 610, fifth capacitor pads 610′, and sixth capacitor pads 720 on an upper surface thereof. The sixth capacitor pads 720 may be dummy pads insulated from conduction materials inside or outside the second decoupling semiconductor capacitor 501e.

Third chip pads 210 may be electrically connected to the sixth capacitor pads 720 by fifth bonding wires 211, and the sixth capacitor pads 720 may be electrically connected to the third bond fingers 820 by sixth bonding wires 721. Fourth chip pads 260 may be electrically connected to the fourth capacitor pads 610 by seventh bonding wires 611, and the fifth capacitor pads 610′ may be electrically connected to the fourth bond fingers 870 via eighth bonding wires 611′.

The third chip pad 210 may include a terminal serving as a signal pin, and the fourth chip pad 260 may include a terminal serving as a power/ground pin.

Although one or more decoupling semiconductor capacitors 501d and 501e are mounted within the semiconductor package 21 as illustrated in FIGS. 7D and 7E, the decoupling semiconductor capacitors 501d and 501e do not significantly affect a height of the semiconductor package 21. In addition, the third and sixth capacitor pads 710 and 720 are formed on the upper surfaces of the first and second decoupling semiconductor capacitors 501d and 501e, respectively, to prevent the bonding wires connecting signal pads of the semiconductor chip and the bond fingers of the packaging substrate from becoming excessively long.

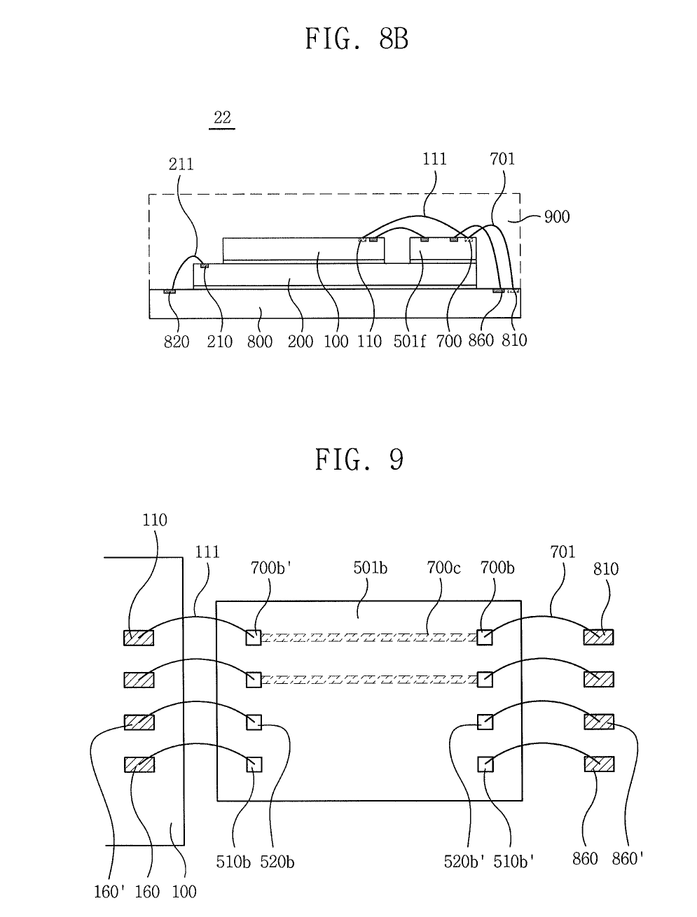

FIG. 8A illustrates a top view of a semiconductor package 22 according to another example embodiment and FIG. 8B illustrates an internal side view of the semiconductor package 22.

Referring to FIGS. 8A and 8B, the semiconductor package 22 may include a packaging substrate 800, a second semiconductor chip 200 mounted on the packaging substrate 800, and a first semiconductor chip 100 stacked on the second semiconductor chip 200. An area of a bottom surface of the first semiconductor chip 100 may be equal to or smaller than that of the second semiconductor chip 200. In addition, the semiconductor package 22 may include a decoupling semiconductor capacitor 501f mounted on the second semiconductor chip 200 and electrically connected to the first semiconductor chip 100. The decoupling semiconductor capacitor 501f and the first semiconductor chip 100 may be mounted in direct contact with the semiconductor chip 200 or in contact with the semiconductor chip 200 via adhesion layers.

The decoupling semiconductor capacitor 501f may include third capacitor pads 700. The third capacitor pads 700 may be electrically connected to the pads 110 of the first semiconductor chip 100 serving as signal pins by bonding wires 111. The chip pads 210 of the second semiconductor chip 200 including terminals serving as signal pins may be electrically connected to bond fingers 820 formed along one side edge of the packaging substrate 800 by bonding wires 211.

The decoupling semiconductor capacitor 501f may be mounted on the remaining space of an upper surface of the second semiconductor chip 200, i.e., a space that is not occupied by the first semiconductor chip 100. The decoupling semiconductor capacitor 501f may have the same height as the first semiconductor chip 100.

The third capacitor pads 700 may be electrically connected to bond fingers 810 formed along an opposite side edge of the packaging substrate 800 by bonding wires 701.

FIG. 9 illustrates a partial top view illustrating a connection state of a semiconductor package that employs the decoupling semiconductor capacitor 501b of FIG. 5D according to an example embodiment. Referring to FIG. 9, one of the bond fingers 810 may be connected to the first dummy capacitor pad 700b by the bonding wire 701, the first dummy capacitor pad 700b may be connected to the second dummy capacitor pad 700b′ by the distribution line 700c, and the second dummy capacitor pad 700b′ may be connected to one of chip pads 110 by a bonding wire 111. Other elements not described herein will be understood from the elements of the same or similar reference numbers in other example embodiments of the specification. According to the present example embodiment, lengths of all the bonding wires 111 and 701 may be standardized so that a process for connecting the bonding wires 111 and 701 can be simplified. In addition, the lengths of the bonding wires 111 and 701 may be made shorter so that the electrical and electronic effects caused by the decoupling semiconductor capacitor 501b can be minimized.

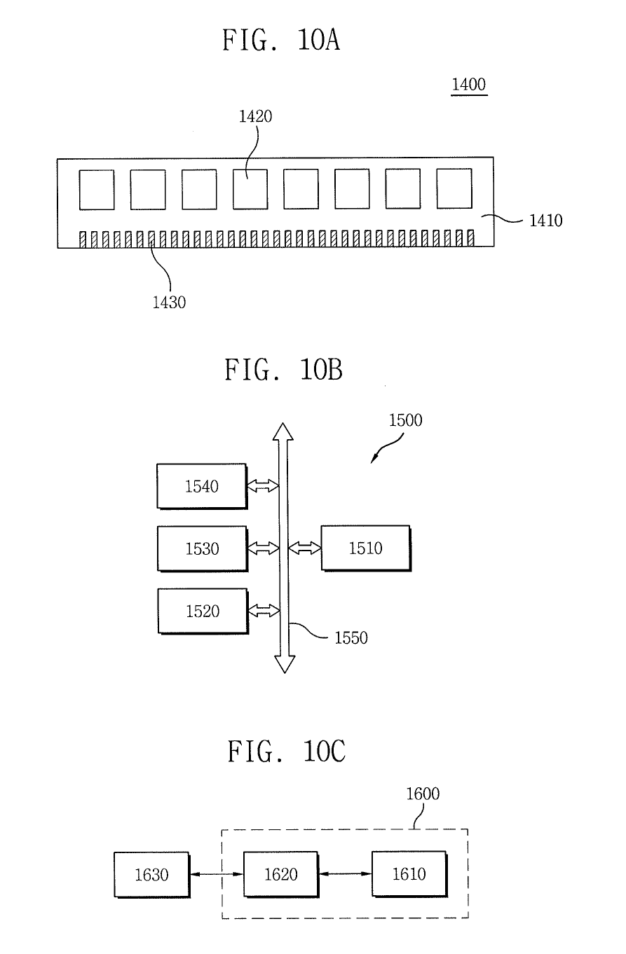

FIGS. 10A to 10C illustrate block diagrams illustrating a semiconductor module, an electronic system, and a memory card including various semiconductor packages according to example embodiments.

Referring to FIG. 10A, the above described semiconductor packages 10 to 22 may be employed in a semiconductor module 1400 including various kinds of semiconductor devices. The semiconductor module 1400 may include a module substrate 1410, semiconductor integrated circuit (IC) chips 1420 mounted on the module substrate 1410, and module contact terminals 1430 formed in a row on one side of the module substrate 1410 and electrically connected to the semiconductor IC chips 1420. The semiconductor IC chips 1420 may employ the package techniques of the example embodiments. The semiconductor module 1400 may be connected to an external electronic device via the module contact terminals 1430.

Referring to FIG. 10B, the above described semiconductor packages 10 to 22 may be employed in an electronic system 1500. The electronic system 1500 may include a controller 1510, an I/O device 1520, and a storage device 1530. The controller 1510, the I/O device 1520, and the storage device 1530 may be combined via a bus 1550 providing a data path. The controller 1510 may include one or more of a microprocessor, a digital signal processor, a microcontroller, and a logic device. The controller 1510 and the storage device 1530 may include one or more of the semiconductor packages 10 to 22 according to the example embodiments. The I/O device 1520 may include one or more of a keypad, a keyboard, a display device, etc. The storage device 1530 may store data and/or commands executed by the controller 1510. The storage device 1530 may include a volatile memory device, such as a DRAM, and/or a non-volatile memory device, such as a flash memory. For example, the flash memory may be mounted in an information processing system such as a mobile device or a desktop computer. The flash memory may be implemented as a solid state disk (SSD).

The electronic system 1500 may further include an interface 1540 for transferring data to a communication network or receiving data from the communication network. The interface 1540 may be a wired-wireless type. For example, the interface 1540 may include an antenna, a wired-wireless transceiver, etc. The electronic system 1500 may be implemented as a mobile system, a personal computer, an industrial computer, a logic system which performs various functions, etc. For example, the mobile system may be a personal digital assistant (PDA), a portable computer, a tablet, a mobile phone, a wireless phone, a laptop computer, a memory card, a digital music system, an information transmission/reception system, etc.

Referring to FIG. 10C, the above described semiconductor packages 10 to 22 according to the example embodiments may be provided in a form of a memory card 1600. In an example embodiment, the memory card 1600 may include a nonvolatile storage device 1610 and a memory controller 1620. The nonvolatile storage device 1610 and the memory controller 1620 may store data or read the stored data. The nonvolatile storage device 1610 may include one or more nonvolatile memory devices employing the semiconductor package techniques according to the example embodiments. The memory controller 1620 may control the nonvolatile storage device 1610 to read the stored data or to store data in response to a read/write request of a host 1630.

Additionally, the terms and functions of elements which are not indicated by the reference numbers or indicated only by the reference numbers will be easily understood from other drawings and their descriptions of the specification.

As described above, semiconductor packages according to example embodiments may enable an increase in the degree of freedom of a mounting position of a decoupling semiconductor capacitor within the semiconductor package. The package may be improved by using a silicon wafer-based decoupling semiconductor capacitor in accordance with the above described example embodiments. As described above, the space occupied by the decoupling semiconductor capacitor may be effectively arranged to prevent the decoupling semiconductor capacitor from excessively occupying the space within the semiconductor package. In addition, the volume of the semiconductor package may be reduced by using the decoupling semiconductor capacitor, so that a high density semiconductor package can be implemented.

Furthermore, when a packaging substrate, a semiconductor chip, and a decoupling semiconductor capacitor are electrically connected by bonding wires according to the example embodiments, an increase in length of bonding wires may be avoided so that an effective electrical connection for minimizing inductance caused by the decoupling semiconductor capacitor can be obtained.

As described above, embodiments may provide a semiconductor package in which one or more semiconductor chips are mounted, and all or some of the semiconductor chips are electrically connected to a decoupling semiconductor capacitor. A positioning technology of semiconductor chips and a capacitor mounted in a package according to embodiments may overcome size and height issues of a package. 3-D decoupling capacitors that can be manufactured based on a semiconductor fabrication process may be used as the capacitor. In a high-speed memory chip, a ground power pin may be electrically connected to the capacitor.

By way of summation and review, when semiconductor chips and capacitors stacked in a package have a multi-stack structure, and the capacitors are located at the same level as or lower than the semiconductor chips connected thereto, “jumping pads” on the capacitors may be used. In general, signal input/output terminals of chips are directly and electrically connected to a package substrate via bonding wires without being connected to the capacitor. However, in this case, the bonding wires must be elongated, and in contact with edges of the capacitor. Thus, the jumping pads, as dummy pads, may be formed on the capacitor to enable the bonding wire to go through them.

According to embodiments, when the capacitors are disposed on the semiconductor chips electrically connected thereto, the size of the package may be reduced, and, in this case, the jumping pads may be replaced with flip-chip bonding structures. Thus, embodiments provide a semiconductor package in which one or more semiconductor chips and one or more decoupling semiconductor capacitors are mounted, and provide an electronic system including a semiconductor package.

In accordance with an embodiment, a semiconductor package may include a packaging substrate including a first bond finger, a decoupling semiconductor capacitor mounted on the packaging substrate and including a first capacitor pad and a second capacitor pad, and a semiconductor chip mounted on the packaging substrate and including a first chip pad. The first bond finger may be electrically connected to the first capacitor pad, the second capacitor pad may be electrically connected to the first chip pad, and the first capacitor pad and the second capacitor pad may be electrically connected to each other. In accordance with an embodiment, an electronic system may include an input/output (I/O) device, and a semiconductor package formed adjacent to and electrically connected to the I/O device.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a packaging substrate including a first bond finger and a second bond finger;
a first semiconductor chip mounted on the packaging substrate, and including a first chip pad and a second chip pad, the first bond finger being electrically connected to the first chip pad by a first bonding wire, and the second bond finger being electrically connected to the second chip pad by a second bonding wire; and
a first decoupling semiconductor capacitor mounted on the first semiconductor chip, and including a first capacitor pad, the first capacitor pad being electrically connected to the second chip pad.

2. The semiconductor package as claimed in claim 1, wherein the first capacitor pad is electrically connected to the second chip pad by a third bonding wire.

3. The semiconductor package as claimed in claim 1, wherein the first semiconductor chip further includes a land that is electrically connected to the second chip pad by a distribution line formed on an upper surface of the first semiconductor chip or within the first semiconductor chip, and
the land is electrically connected to the first capacitor pad by a flip chip bonding method.

4. The semiconductor package as claimed in claim 1, wherein the first decoupling semiconductor capacitor includes:
the first capacitor pad;
a capacitor substrate;
a lower electrode on the capacitor substrate;
a dielectric layer on the lower electrode;
an upper electrode on the dielectric layer, the first capacitor pad being electrically connected to the upper electrode; and
a second capacitor pad electrically connected to the lower electrode.

5. The semiconductor package as claimed in claim 4, wherein:
the second bond finger includes a bond finger for ground,
the second chip pad includes a chip pad for ground,
the first capacitor pad includes a capacitor pad for ground, and
the bond finger for ground, the chip pad for ground, and the capacitor pad for ground are electrically connected.

6. The semiconductor package as claimed in claim 5, wherein:
the packaging substrate includes a bond finger for power,
the first semiconductor chip includes a chip pad for power,
the second capacitor pad includes a capacitor pad for power, and
the bond finger for power, the chip pad for power, and the capacitor pad for power are electrically connected.

7. The semiconductor package as claimed in claim 4, wherein the first decoupling semiconductor capacitor includes a dummy capacitor pad insulated from the upper electrode and the lower electrode.

8. The semiconductor package as claimed in claim 1, further comprising a second semiconductor chip mounted on the packaging substrate, the second semiconductor chip including a third chip pad,
wherein the packaging substrate further includes a third bond finger electrically connected to the third chip pad.

9. The semiconductor package as claimed in claim 8, further comprising a second decoupling semiconductor capacitor mounted on the second semiconductor chip.

10. The semiconductor package as claimed in claim 9, wherein the second decoupling semiconductor capacitor includes:
a capacitor substrate;
a lower electrode on the capacitor substrate;
a dielectric layer on the lower electrode;
an upper electrode on the dielectric layer;
a third capacitor pad electrically connected to the upper electrode; and
a fourth capacitor pad electrically connected to the lower electrode.

11. The semiconductor package as claimed in claim 10, wherein:
the packaging substrate further includes a fourth bond finger,
the second semiconductor chip further includes a fourth chip pad, and
the fourth bond finger, the fourth chip pad, and the third capacitor pad are electrically connected.

12. The semiconductor package as claimed in claim 11, wherein the second semiconductor chip is mounted between the packaging substrate and the first semiconductor chip.

13. A semiconductor package, comprising:
a packaging substrate including a first bond finger, a second bond finger, and a third bond finger;
a first decoupling semiconductor capacitor mounted on the packaging substrate, the first decoupling semiconductor capacitor including a first capacitor pad, a second capacitor pad, and a third capacitor pad, the first capacitor pad being electrically connected to a first electrode of the first decoupling semiconductor capacitor, the second capacitor pad being electrically connected to a second electrode of the first decoupling semiconductor capacitor, and the third capacitor pad being electrically insulated from the first electrode and the second electrode of the first decoupling semiconductor capacitor;
a first semiconductor chip mounted on the packaging substrate, the first semiconductor chip including a first chip pad, a second chip pad, and a third chip pad;
a first bonding wire electrically connecting the first bond finger and the first capacitor pad;
a second bonding wire electrically connecting the first capacitor pad and the first chip pad;
a third bonding wire electrically connecting the second bond finger and the second capacitor pad;
a fourth bonding wire directly and electrically connecting the second capacitor pad and the second chip pad;
a fifth bonding wire electrically connecting the third bond finger and the third capacitor pad; and
a sixth bonding wire electrically connecting the third capacitor pad and the third chip pad.

14. The semiconductor package as claimed in claim 13, wherein:
the first chip pad is a signal input/output pad,
the second chip pad is a power pad, and
the third chip pad is a ground pad.

15. The semiconductor package as claimed in claim 13, further comprising a second semiconductor chip mounted between the packaging substrate and the first semiconductor chip,
wherein the first decoupling semiconductor capacitor is mounted on the second semiconductor chip.

16. A semiconductor device package, comprising:
a packaging substrate;
a semiconductor chip on the packaging substrate;
an encapsulant, the encapsulant enclosing the semiconductor chip, the semiconductor chip being between the packaging substrate and the encapsulant; and
a semiconductor capacitor device, the semiconductor capacitor device being separate from the semiconductor chip and electrically coupled a power connection of the semiconductor chip, the capacitor device being within the encapsulant.

17. The semiconductor device package as claimed in claim 16, wherein the power connection is supplied with a power supply voltage or a ground voltage.

18. The semiconductor device package as claimed in claim 16, wherein the semiconductor capacitor device is directly affixed to the semiconductor chip by at least one of an adhesive layer and a solder joint.

19. The semiconductor device package as claimed in claim 16, wherein the semiconductor capacitor device is directly affixed to the packaging substrate by at least one of an adhesive layer and a solder joint.

20. The semiconductor device package as claimed in claim 19, wherein the semiconductor chip is directly affixed to the packaging substrate by at least one of an adhesive layer and a solder joint.
